(19) United States
(12) Patent Application Publication
(10) Pub. No.: US 2014/0285073 A1
(43) Pub. Date: Sep. 25, 2014

(54) DEVICE HOUSING WITH ONE OR MORE CHAMFERED CORNERS

(71) Applicants: Hyun Ho Kim, Austin, TX (US); Sudong Cho, Arlington Heights, IL (US); Jomichael Porter, Addison, TX (US)

(72) Inventors: Hyun Ho Kim, Austin, TX (US); Sudong Cho, Arlington Heights, IL (US); Jomichael Porter, Addison, TX (US)

(21) Appl. No.: 13/847,098

(22) Filed: Mar. 19, 2013

(51) Int. Cl. H05K 5/02; A47B 81/06; A47B 96/00

(52) U.S. Cl. CPC H05K 5/02; A47B 96/00; A47B 81/06
USPC 312/7.2; 312/352; 312/223.1

(57) ABSTRACT

Disclosed is an apparatus which provides a housing for hardware device inserts. The device housing may include one or more chamfered corners. According to one example, the housing may be a substantially rectangular housing that includes six primary sides and a chamfered corner contiguous with at least three of the six primary sides.

### TECHNICAL FIELD OF THE APPLICATION

This application relates to an apparatus that provides a housing for a product insert, and more specifically to a housing that has at least one chamfered corner that accommodates a device insert, such as a speaker, a display or other consumer product.

### BACKGROUND OF THE APPLICATION

Conventionally, the design of a speaker or a display housing is a rectangular box with various hardware components mounted inside the box which are otherwise hidden from an outside view perspective. As new shapes and housing configurations have emerged over the years, the design considerations have begun to include other shapes and designs to cater to the consumer's preferred design aesthetics and preferences. However, none of the previous device housings have been constructed to provide a hardware configuration of the present application.

### SUMMARY OF THE APPLICATION

One embodiment of the present application may include an apparatus that includes a substantially rectangular housing comprising six primary sides and at least one chamfered corner contiguous with at least three of the six primary sides.

Another embodiment of the present application may include an apparatus that includes a housing with six sides, and at least one chamfered corner contiguous with at least three of the six sides, wherein a surface area of the chamfered corner is substantially less than a surface area of any of the six sides.

### BRIEF DESCRIPTION OF THE DRAWINGS

FIG. 1A is a front elevational view of a rectangular prism with one corner chamfered, a stylized triangular icon on the face of that chamfer, and a scooped area in the front with a metallic insert.

FIG. 1B is a right elevational view of a rectangular prism with one corner chamfered, a stylized triangular icon on the face of that chamfer, and a scooped area in the front with a metallic insert.

FIG. 1C is a top elevational view of a rectangular prism with one corner chamfered, a stylized triangular icon on the face of that chamfer, and a scooped area in the front with a metallic insert.

FIG. 1D is a trimetric view of a rectangular prism with one corner chamfered, a stylized triangular icon on the face of that chamfer, and a scooped area in the front with a metallic insert.

FIG. 2A is a front elevational view of a rectangular prism with one corner chamfered and a stylized triangular icon on the face of that chamfer.

FIG. 2B is a right elevational view of a rectangular prism with one corner chamfered and a stylized triangular icon on the face of that chamfer.

FIG. 2C is a top elevational view of a rectangular prism with one corner chamfered and a stylized triangular icon on the face of that chamfer.

FIG. 2D is a trimetric view of a rectangular prism with one corner chamfered and a stylized triangular icon on the face of that chamfer.

FIG. 3A is a front elevational view of a rectangular prism with two corners chamfered and a stylized triangular icon on the face of each chamfer.

FIG. 3B is a right elevational view of a rectangular prism with two corners chamfered and a stylized triangular icon on the face of each chamfer.

FIG. 3C is a top elevational view of a rectangular prism with two corners chamfered and a stylized triangular icon on the face of each chamfer.

FIG. 3D is a trimetric view of a rectangular prism with two corners chamfered and a stylized triangular icon on the face of each chamfer.

FIG. 4A is a front elevational view of a rectangular prism with two corners chamfered.

FIG. 4B is a right elevational view of a rectangular prism with two corners chamfered.

FIG. 4C is a top elevational view of a rectangular prism with two corners chamfered.

FIG. 4D is a trimetric view of a rectangular prism with two corners chamfered.

FIG. 5A is a front elevational view of a rectangular prism with four corners chamfered.

FIG. 5B is a right elevational view of a rectangular prism with four corners chamfered.

FIG. 5C is a top elevational view of a rectangular prism with four corners chamfered.

FIG. 5D is a trimetric view of a rectangular prism with four corners chamfered.

FIG. 6A is a front elevational view of a cube with one corner chamfered and a stylized triangular icon on the face of that chamfer.

FIG. 6B is a right elevational view of a cube with one corner chamfered and a stylized triangular icon on the face of that chamfer.

FIG. 6C is a top elevational view of a cube with one corner chamfered and a stylized triangular icon on the face of that chamfer.

FIG. 6D is a trimetric view of a cube with one corner chamfered and a stylized triangular icon on the face of that chamfer.

FIG. 7A is a front elevational view of a cube with two corners chamfered.

FIG. 7B is a right elevational view of a cube with two corners chamfered.

FIG. 7C is a top elevational view of a cube with two corners chamfered.

FIG. 7D is a trimetric view of a cube with two corners chamfered.

FIG. 8A is a front elevational view of a cube with four corners chamfered.

FIG. 8B is a right elevational view of a cube with four corners chamfered.

FIG. 8C is a top elevational view of a cube with four corners chamfered.

FIG. 8D is a trimetric view of a cube with four corners chamfered.

FIG. 9A is a front elevational view of a cube with two opposing corners chamfered.

FIG. 9B is a right elevational view of a cube with two opposing corners chamfered.

FIG. 9C is a top elevational view of a cube with two opposing corners chamfered.

FIG. 9D is a trimetric view of a cube with two opposing corners chamfered.

FIG. 10A is a front elevational view of a square based pyramid with one base corner chamfered.

FIG. 10B is a right elevational view of a square based pyramid with one base corner chamfered.

FIG. 10C is a top elevational view of a square based pyramid with one base corner chamfered.

FIG. 10D is a trimetric view of a square based pyramid with one base corner chamfered.

FIG. 11A is a front elevational view of a tetrahedron with one corner chamfered and a stylized triangular icon on the face of that triangle.

FIG. 11B is a right elevational view of a tetrahedron with one corner chamfered and a stylized triangular icon on the face of that triangle.

FIG. 11C is a top elevational view of a tetrahedron with one corner chamfered and a stylized triangular icon on the face of that triangle.

FIG. 11D is a trimetric view of a tetrahedron with one corner chamfered and a stylized triangular icon on the face of that triangle.

FIG. 12A is a front elevational view of a tetrahedron with one corner chamfered.

FIG. 12B is a right elevational view of a tetrahedron with one corner chamfered.

FIG. 12C is a top elevational view of a tetrahedron with one corner chamfered.

FIG. 12D is a trimetric view of a tetrahedron with one corner chamfered.

FIG. 13A is a front elevational view of a tetrahedron with two corner chamfered.

FIG. 13B is a right elevational view of a tetrahedron with two corner chamfered.

FIG. 13C is a top elevational view of a tetrahedron with two corner chamfered.

FIG. 13D is a trimetric view of a tetrahedron with two corner chamfered.

FIG. 14A is a front elevational view of a rectangular frame with one corner chamfered, a stylized triangular icon on the face of that chamfer, and a recessed area in the center.

FIG. 14B is a right elevational view of a rectangular frame with one corner chamfered, a stylized triangular icon on the face of that chamfer, and a recessed area in the center.

FIG. 14C is a top elevational view of a rectangular frame with one corner chamfered, a stylized triangular icon on the face of that chamfer, and a recessed area in the center.

FIG. 14D is a trimetric view of a rectangular frame with one corner chamfered, a stylized triangular icon on the face of that chamfer, and a recessed area in the center.

FIG. 15A is a front elevational view of a sphere with a flat face cut into it and a stylized triangular icon on that face.

FIG. 15B is a right elevational view of a sphere with a flat face cut into it and a stylized triangular icon on that face.

FIG. 15C is a top elevational view of a sphere with a flat face cut into it and a stylized triangular icon on that face.

FIG. 15D is a trimetric view of a sphere with a flat face cut into it and a stylized triangular icon on that face.

FIG. 16A is a front elevational view of a square tile with one corner chamfered, a stylized triangular icon on the face of that chamfer, and a scooped area in the front with a metallic insert.

FIG. 16B is a right elevational view of a square tile with one corner chamfered, a stylized triangular icon on the face of that chamfer, and a scooped area in the front with a metallic insert.

FIG. 16C is a top elevational view of a square tile with one corner chamfered, a stylized triangular icon on the face of that chamfer, and a scooped area in the front with a metallic insert.

FIG. 16D is a trimetric view of a square tile with one corner chamfered, a stylized triangular icon on the face of that chamfer, and a scooped area in the front with a metallic insert.

FIG. 17A is a front elevational view of a rectangular prism with one corner chamfered, a stylized triangular icon on the face of that chamfer, a scooped area in the front with a metallic insert, and a rectangular recess inside the insert.

FIG. 17B is a right elevational view of a rectangular prism with one corner chamfered, a stylized triangular icon on the face of that chamfer, a scooped area in the front with a metallic insert, and a rectangular recess inside the insert.

FIG. 17C is a top elevational view of a rectangular prism with one corner chamfered, a stylized triangular icon on the face of that chamfer, a scooped area in the front with a metallic insert, and a rectangular recess inside the insert.

FIG. 17D is a trimetric view of a rectangular prism with one corner chamfered, a stylized triangular icon on the face of that chamfer, a scooped area in the front with a metallic insert, and a rectangular recess inside the insert.

### DETAILED DESCRIPTION OF THE APPLICATION

It will be readily understood that the components of the present application, as generally described and illustrated in the figures herein, may be arranged and designed in a wide variety of different configurations. Thus, the following detailed description of the embodiments of an apparatus, as represented in the attached figures, is not intended to limit the scope of the application as claimed, but is merely representative of selected embodiments of the application.

The features, structures, or characteristics of the application described throughout this specification may be combined in any suitable manner in one or more embodiments. For example, the usage of the phrases “example embodiments”, “some embodiments”, or other similar language, throughout this specification refers to the fact that a particular feature, structure, or characteristic described in connection with the embodiment may be included in at least one embodiment of the present application. Thus, appearances of the phrases “example embodiments”, “in some embodiments”, “in other embodiments”, or other similar language, throughout this specification do not necessarily all refer to the same group of embodiments, and the described features, structures, or characteristics may be combined in any suitable manner in one or more embodiments.

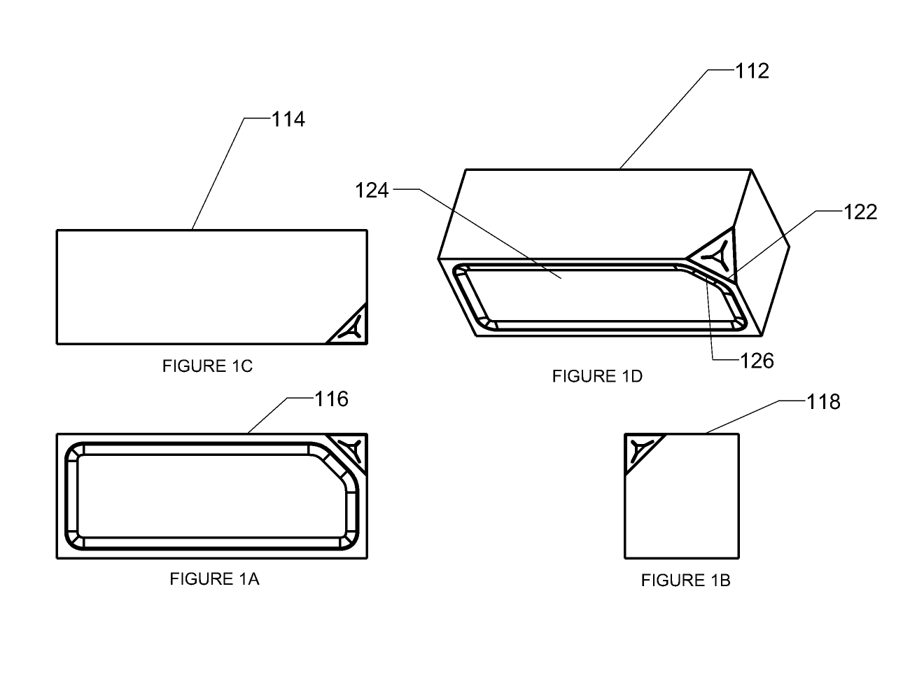

FIG. 1A is a front elevational view of a rectangular prism with one corner chamfered, a stylized triangular icon on the face of that chamfer, and a scooped area in the front with a metallic insert. Referring to FIG. 1A, a hollow side or empty side is exposed 116 and the chamfered corner is observed as being a slanted surface. The open side permits a device insert to be placed into the housing, such as a speaker, display or other functional insert. In FIG. 1A, the edge of the open side may have a lip with a small surface area that is substantially smaller than the surface area of the enclosed sides (e.g., the lip surface area of the open side may be 25%, 10%, 5% or less of the total surface area of the enclosed sides).

FIG. 1B is a right elevational view of a rectangular prism with one corner chamfered, a stylized triangular icon on the face of that chamfer, and a scooped area in the front with a metallic insert. Referring to FIG. 1B, the side view provides a view of the side face 118 with the chamfered corner.

FIG. 1C is a top elevational view of a rectangular prism with one corner chamfered, a stylized triangular icon on the face of that chamfer, and a scooped area in the front with a metallic insert. Referring to FIG. 1C, the front view of the rear side of the housing 114 provides a view of an enclosed side as opposed to the open side in FIG. 1A.

FIG. 1D is a trimetric view of a rectangular prism with one corner chamfered, a stylized triangular icon on the face of that chamfer, and a scooped area in the front with a metallic insert. Referring to FIG. 1D, the rectangular prism 112 includes a chamfered corner 122 that is contiguous with three of the sides of the prism including a top side, a right side and an open side that permits the open area 124 to receive an insert that is placed inside the open face. The open side 124 may have five edges in this example, the first four edges are based on the shape of the housing as a rectangular prism, and the fifth edge is a bottom edge of the chamfered corner which adds an additional edge to the open side 124.

According to an example embodiment, the housing may provide a substantially rectangular housing with the exception of the chamfered corner that includes six primary sides based on the structure of a rectangular prism. The housing may include at least one chamfered corner contiguous with at least three of the six primary sides as may be observed from FIG. 1D. In FIG. 1D, the chamfered corner 122 has a triangular shaped surface area which may be an equilateral triangle or an isosceles triangle. In FIG. 1D, the inserted hardware may be a deformable insert located inside the housing which is exposed to the exterior of the housing via a removed face and which is contiguous with the lip portion. The deformable insert may be a deformable speaker that is flexible and which may be form-fitted into the open side of the housing. The deformable insert may instead by an electronic display with at least one chamfered corner or which has a deformable frame that can be form-fitted into the open side of the housing.

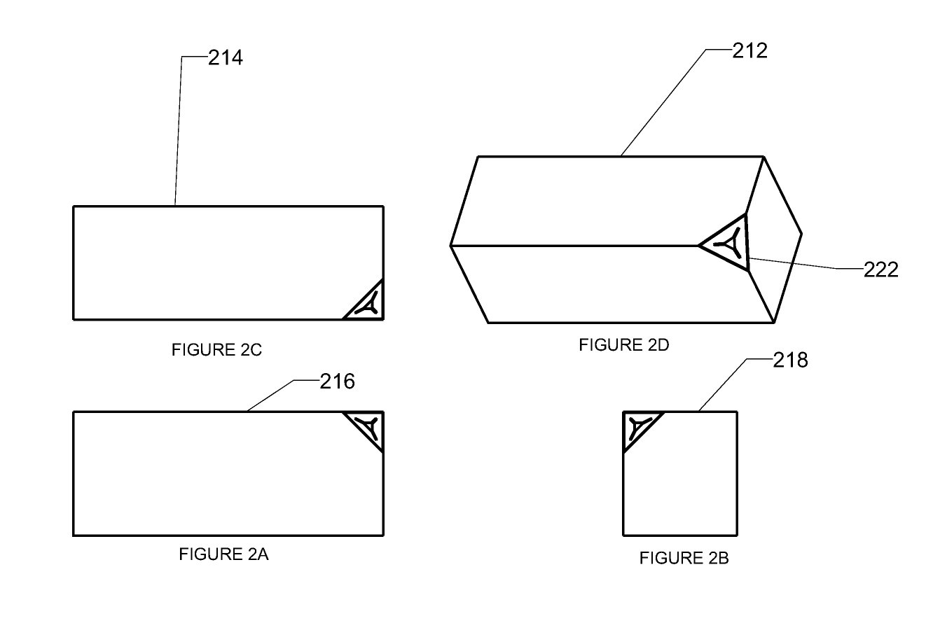

FIG. 2A is a front elevational view of a rectangular prism with one corner chamfered and a stylized triangular icon on the face of that chamfer. Referring to FIG. 2A, the front view of the rectangular prism provides an enclosed side 216 and a chamfered corner. FIG. 2B is a right elevational view of a rectangular prism with one corner chamfered and a stylized triangular icon on the face of that chamfer. Referring to FIG. 2B, the side view provides an enclosed side 218 on the right side of the prism.

FIG. 2C is a top elevational view of a rectangular prism with one corner chamfered and a stylized triangular icon on the face of that chamfer. Referring to FIG. 2C, the rear side view of the prism 214 provides a view of an enclosed side and the chamfered corner. FIG. 2D is a trimetric view of a rectangular prism with one corner chamfered and a stylized triangular icon on the face of that chamfer. Referring to FIG. 2D, the front side view 212 provides a view of a chamfered corner 222 that is not contiguous with any open or exposed sides.

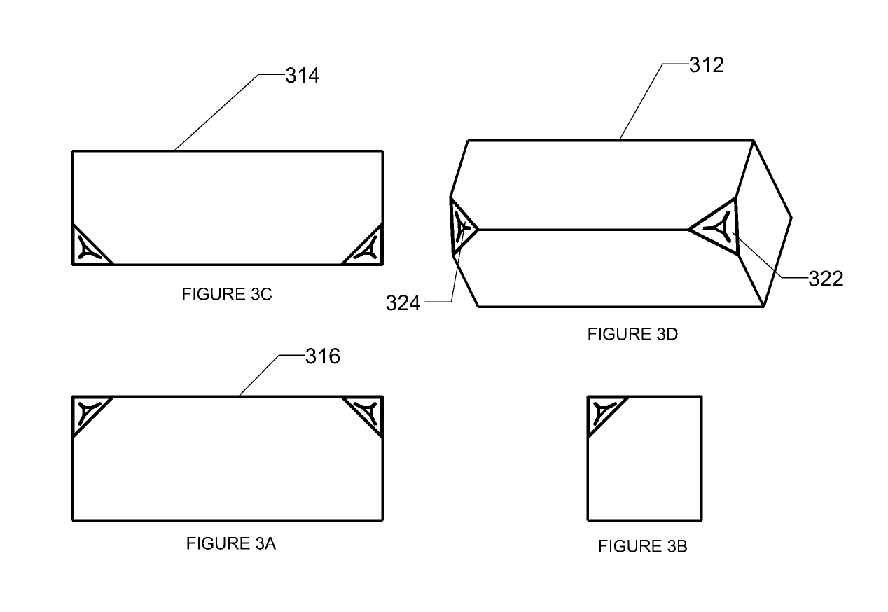

FIG. 3A is a front elevational view of a rectangular prism with two corners chamfered and a stylized triangular icon on the face of each chamfer. Referring to FIG. 3A, the side 316 has two chamfered corners. FIG. 3B is a right elevational view of a rectangular prism with two corners chamfered and a stylized triangular icon on the face of each chamfer. Referring to FIG. 3B, the side view 318 demonstrates one chamfered corner as viewed from the side.

FIG. 3C is a top elevational view of a rectangular prism with two corners chamfered and a stylized triangular icon on the face of each chamfer. Referring to FIG. 3C, the rear side view 314 of the prism provides a view of two chamfered corners. FIG. 3D is a trimetric view of a rectangular prism with two corners chamfered and a stylized triangular icon on the face of each chamfer. According to example embodiments, the prism housing 312 may include at least one additional chamfered corner contiguous with at least three of the six primary sides. In FIG. 3D, the chamfered corners 322 and 324 each share two sides that are contiguous with both chamfered corners. The chamfered corners may share one or two sides of the prism that are contiguous with both the chamfered corners. In the example of FIG. 3D, the additional chamfered corner 324 is contiguous with only two of the same three primary sides as the first chamfered corner 322. Being ‘contiguous’ means that the chamfered corner is in contact with the side. Each of the sides of the six sides of the rectangular prism may be considered primary sides, and the sides created by the chamfered corners may be considered secondary sides or non-primary sides.

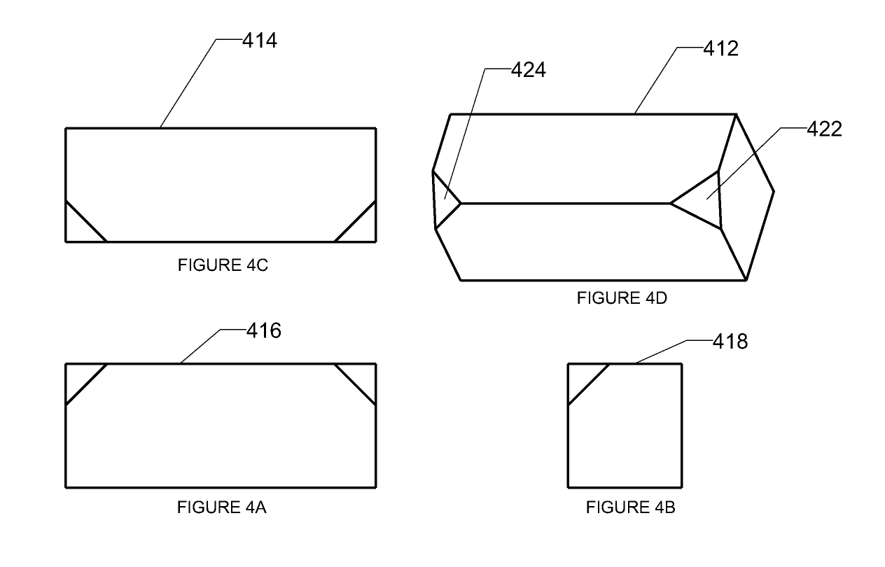

FIG. 4A is a front elevational view of a rectangular prism with two corners chamfered. Like FIG. 3A, the prism includes a view with two chamfered corners on a front side view 416. However, there is no logo or design included on the chamfered corners of this example. FIG. 4B is a right elevational view of a rectangular prism with two corners chamfered on a right side view that provides a view of one of the chamfered corners 418.

FIG. 4C is a top elevational view of a rectangular prism with two corners chamfered. Referring to FIG. 4C, the rear side view 414 illustrates two chamfered corners. FIG. 4D is a trimetric view of a rectangular prism with two corners chamfered. Referring to FIG. 4D, the prism 412 illustrates a first chamfered corner 422 and a second chamfered corner 424.

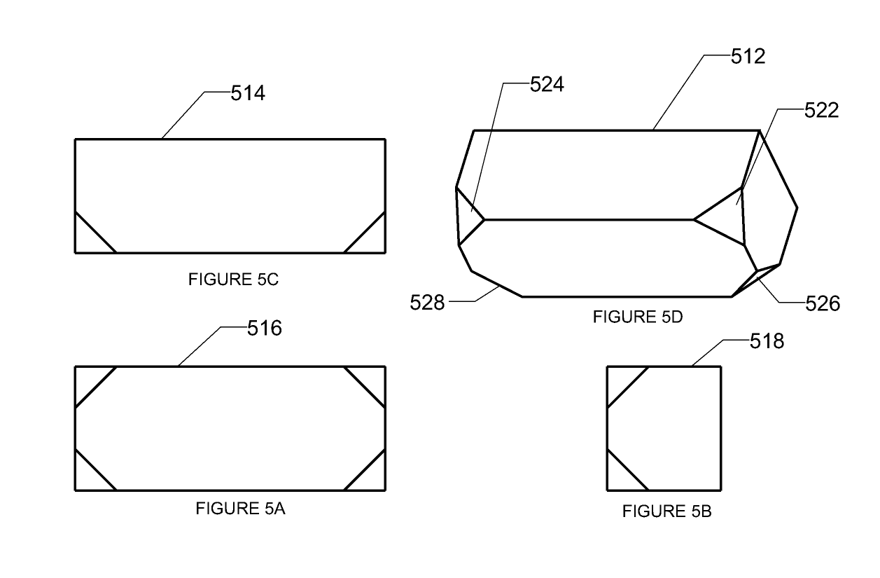

FIG. 5A is a front elevational view of a rectangular prism with four corners chamfered. Referring to FIG. 5A, the front side view 516 includes four chamfered corners. FIG. 5B is a right elevational view of a rectangular prism with four corners chamfered. Referring to FIG. 5B, the right side view 518 includes two chamfered corners.

FIG. 5C is a top elevational view of a rectangular prism with four corners chamfered. Referring to FIG. 5C, the top side view 514 includes only two visible chamfered corners although there are four in this example prism. FIG. 5D is a trimetric view of a rectangular prism with four corners chamfered 522, 524, 526 and 528. In this example each of the chamfered corners is contiguous with one of the same sides. In an alternative, only two chamfered sides may share a contiguous side. The chamfered corners provide secondary sides that have substantially less surface area than the six primary sides of the prism. The surface area of the chamfered side may be substantially less than the surface area of the primary sides (e.g., 50% less, 75% less, 90% less, or more).

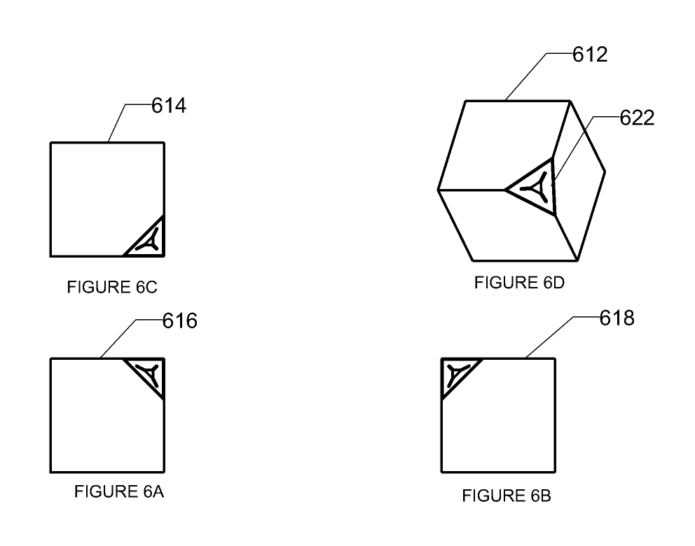

FIG. 6A is a front elevational view of a cube with one corner chamfered and a stylized triangular icon on the face of that chamfer. Referring to FIG. 6A, this view 616 has a chamfered corner. FIG. 6B is a right elevational view of a cube with one corner chamfered and a stylized triangular icon on the face of that chamfer. Referring to FIG. 6B, this view 618 also has a chamfered corner. FIG. 6C is a top elevational view of a cube with one corner chamfered and a stylized triangular icon on the face of that chamfer. Referring to FIG. 6C, this view 614 also has a chamfered corner in view. FIG. 6D is a trimetric view of a cube with one corner chamfered and a stylized triangular icon on the face of that chamfer. In this view 612, the chamfered corner 622 is observed as being contiguous with three sides of the cube.

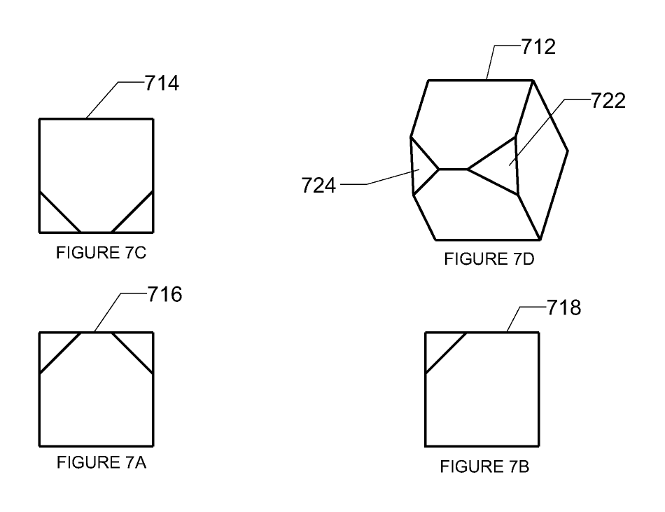

FIG. 7A is a front elevational view of a cube with two corners chamfered. Referring to FIG. 7A, this view 716 has two chamfered corners without any stylized icon. FIG. 7B is a right elevational view of a cube with two corners chamfered. Referring to FIG. 7B, this view 718 has only visible chamfered corner without any stylized icon. FIG. 7C is a top elevational view of a cube with two corners chamfered. Referring to FIG. 7C, this view 714 has two chamfered corners without any stylized icon. FIG. 7D is a trimetric view of a cube with two corners chamfered. Referring to FIG. 7D, this view 712 has two chamfered corners 722 and 724 without any stylized icon. In this example, the two chamfered corners 722 and 724 share two contiguous sides of the cube.

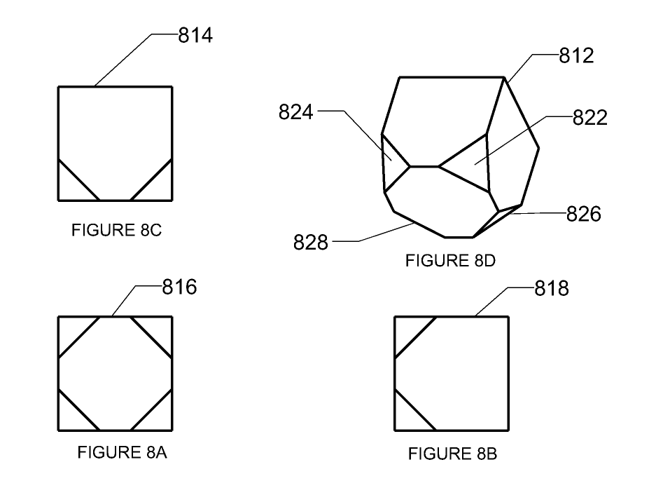

FIG. 8A is a front elevational view of a cube with four corners chamfered. Referring to FIG. 8A, this view 816 has four chamfered corners without any stylized icon. FIG. 8B is a right elevational view of a cube with four corners chamfered. Referring to FIG. 8B, this view 818 has two visible chamfered corners without any stylized icon. FIG. 8C is a top elevational view of a cube with four corners chamfered. Referring to FIG. 8C, this view 814 has two visible chamfered corners without any stylized icon. FIG. 8D is a trimetric view of a cube with four corners chamfered. Referring to FIG. 8D, this view 812 has four chamfered corners 822, 824, 826 and 828 without any stylized icon.

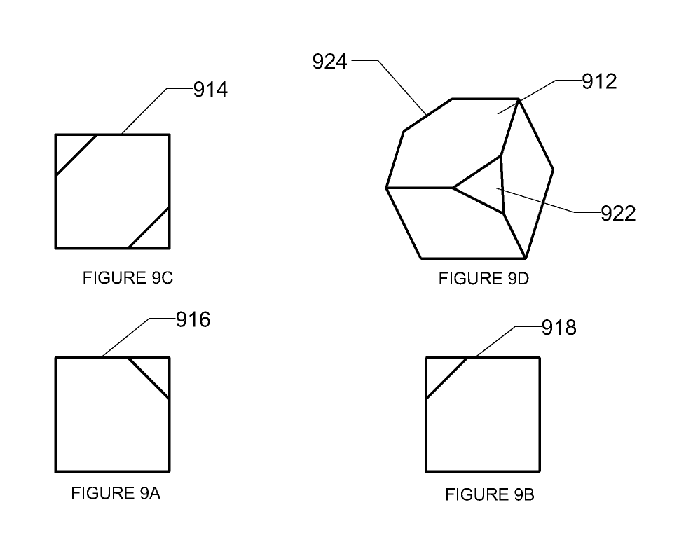

FIG. 9A is a front elevational view of a cube with two opposing corners chamfered. Referring to FIG. 9A, this view 916 has one visible chamfered corner without any stylized icon. FIG. 9B is a right elevational view of a cube with two opposing corners chamfered. Referring to FIG. 9B, this view 918 has one visible chamfered corner. FIG. 9C is a top elevational view of a cube with two opposing corners chamfered. Referring to FIG. 9C, this view 914 has two visible chamfered corners. FIG. 9D is a trimetric view of a cube with two opposing corners chamfered. Referring to FIG. 9D, this view 912 has two visible chamfered corners 922 and 924. In this example, the two chamfered corners only share one contiguous primary side of the cube.

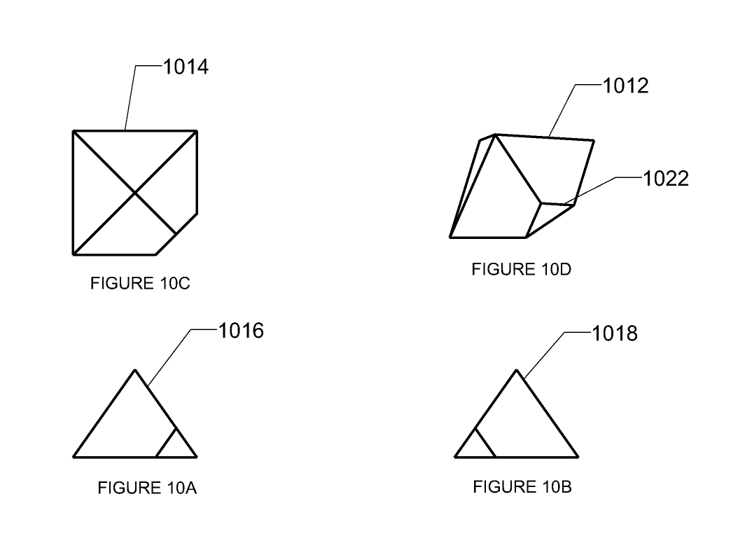

FIG. 10A is a front elevational view of a square based pyramid with one base corner chamfered. Referring to FIG. 10A, this view 1016 has one chamfered corner. FIG. 10B is a right elevational view of a square based pyramid with one base corner chamfered. Referring to FIG. 10B, this view 1018 has one chamfered corner on the opposite side. FIG. 10C is a top elevational view of a square based pyramid with one base corner chamfered. Referring to FIG. 10C, this top view 1014 has one chamfered corner. FIG. 10D is a trimetric view of a square based pyramid with one base corner chamfered. Referring to FIG. 10D, this view 1012 has one chamfered corner 1022.

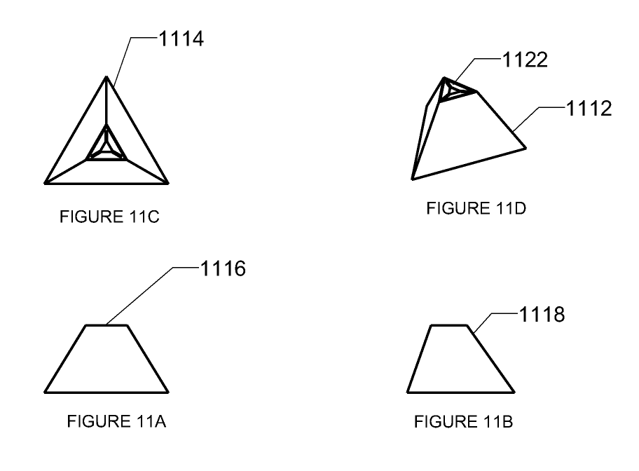

FIG. 11A is a front elevational view of a tetrahedron with one corner chamfered and a stylized triangular icon on the face of that triangle. Referring to FIG. 11A, this view 1116 has one chamfered corner on the top of the tetrahedron. FIG. 11B is a right elevational view of a tetrahedron with one corner chamfered and a stylized triangular icon on the face of that triangle. Referring to FIG. 11B, this view 1118 has one chamfered corner. FIG. 11C is a top elevational view of a tetrahedron with one corner chamfered and a stylized triangular icon on the face of that triangle. Referring to FIG. 11C, this view 1114 has one chamfered corner. FIG. 11D is a trimetric view of a tetrahedron with one corner chamfered and a stylized triangular icon on the face of that triangle. Referring to FIG. 11D, this view 1112 has one chamfered corner 1122 among the four corners of the tetrahedron.

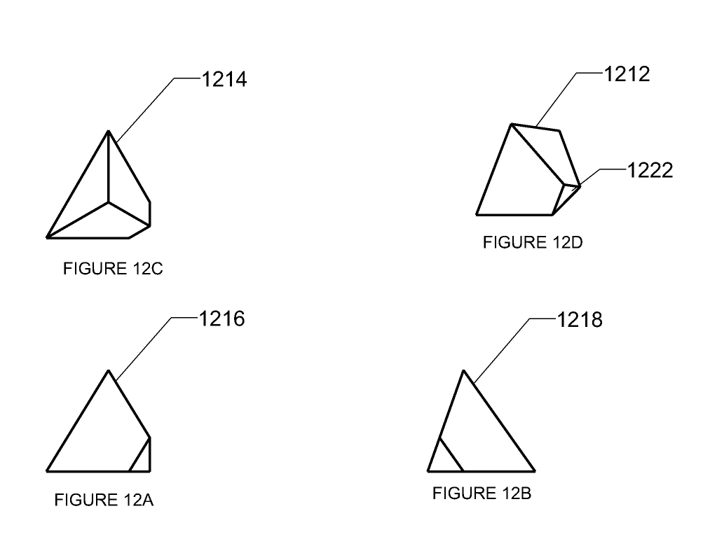

FIG. 12A is a front elevational view of a tetrahedron with one corner chamfered. Referring to FIG. 12A, this view 1216 has one chamfered corner. FIG. 12B is a right elevational view of a tetrahedron with one corner chamfered. Referring to FIG. 12B, this view 1218 has one chamfered corner. FIG. 12C is a top elevational view of a tetrahedron with one corner chamfered. Referring to FIG. 12C, this view 1214 has one chamfered corner. FIG. 12D is a trimetric view of a tetrahedron with one corner chamfered. Referring to FIG. 12D, this view 1212 has one chamfered corner 1222.

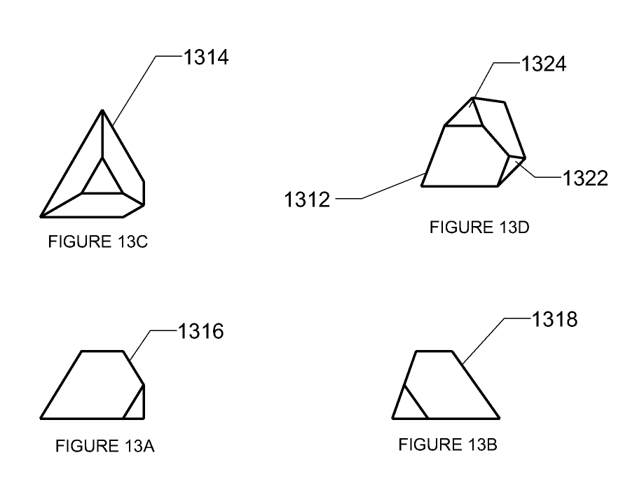

FIG. 13A is a front elevational view of a tetrahedron with two corner chamfered. Referring to FIG. 13A, this view 1316 has two chamfered corners. FIG. 13B is a right elevational view of a tetrahedron with two corner chamfered. Referring to FIG. 13B, this view 1318 has two chamfered corners. FIG. 13C is a top elevational view of a tetrahedron with two corners chamfered. Referring to FIG. 13C, this view 1314 has two chamfered corners. FIG. 13D is a trimetric view of a tetrahedron with two corner chamfered. Referring to FIG. 13D, this view 1312 has two chamfered corners 1322 and 1324.

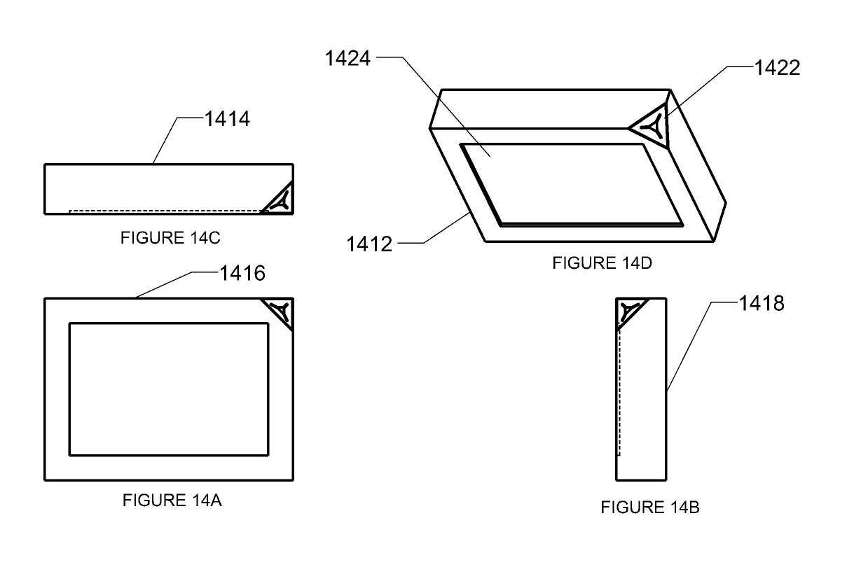

FIG. 14A is a front elevational view of a rectangular frame with one corner chamfered, a stylized triangular icon on the face of that chamfer, and a recessed area in the center. Referring to FIG. 14A, this view 1416 has one chamfered corner and an open side that permits a hardware device to be inserted into the frame area. FIG. 14B is a right elevational view of a rectangular frame with one corner chamfered, a stylized triangular icon on the face of that chamfer, and a recessed area in the center. Referring to FIG. 14B, this view 1418 has one chamfered corner. FIG. 14C is a top elevational view of a rectangular frame with one corner chamfered, a stylized triangular icon on the face of that chamfer, and a recessed area in the center. Referring to FIG. 14C, this view 1414 has one chamfered corner. FIG. 14D is a trimetric view of a rectangular frame with one corner chamfered, a stylized triangular icon on the face of that chamfer, and a recessed area in the center. Referring to FIG. 14D, this view 1412 has one chamfered corner 1422 and a recessed center portion 1424. This configuration may provide a suitable insert area for a display device, speaker or other hardware insert device.

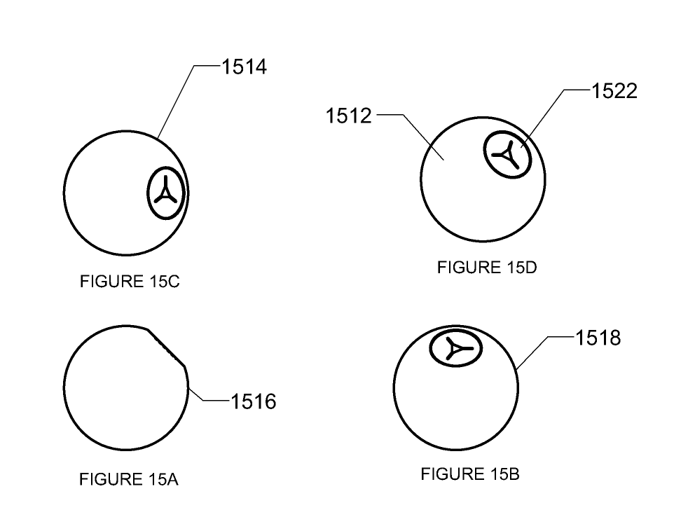

FIG. 15A is a front elevational view of a sphere with a flat face cut into it and a stylized triangular icon on that face. Referring to FIG. 15A, this view 1516 has one chamfered portion. FIG. 15B is a right elevational view of a sphere with a flat face cut into it and a stylized triangular icon on that face 1518. FIG. 15C is a top elevational view of a sphere with a flat face cut into it and a stylized triangular icon on that face 1514. FIG. 15D is a trimetric view of a sphere 1512 with a flat face cut into it 1522 and a stylized triangular icon on that face.

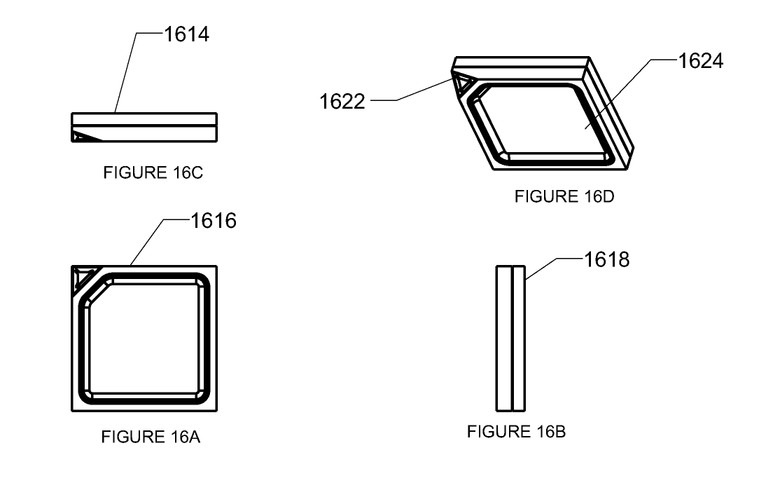

FIG. 16A is a front elevational view of a square tile with one corner chamfered, a stylized triangular icon on the face of that chamfer, and a scooped area in the front with a metallic insert. Referring to FIG. 16A, this view 1616 has one chamfered corner. FIG. 16B is a right elevational view of a square tile with one corner chamfered, a stylized triangular icon on the face of that chamfer, and a scooped area in the front with a metallic insert. Referring to FIG. 16B, this view 1618 has no visible chamfered corner but illustrates the dimensions of the housing. FIG. 16C is a top elevational view of a square tile with one corner chamfered, a stylized triangular icon on the face of that chamfer, and a scooped area in the front with a metallic insert. Referring to FIG. 16C, this view 1614 has one chamfered corner. FIG. 16D is a trimetric view of a square tile with one corner chamfered, a stylized triangular icon on the face of that chamfer, and a scooped area in the front with a metallic insert. Referring to FIG. 16D, this view 1612 has one chamfered corner 1622 and an open center 1624 to allow a hardware device insert to be placed therein.

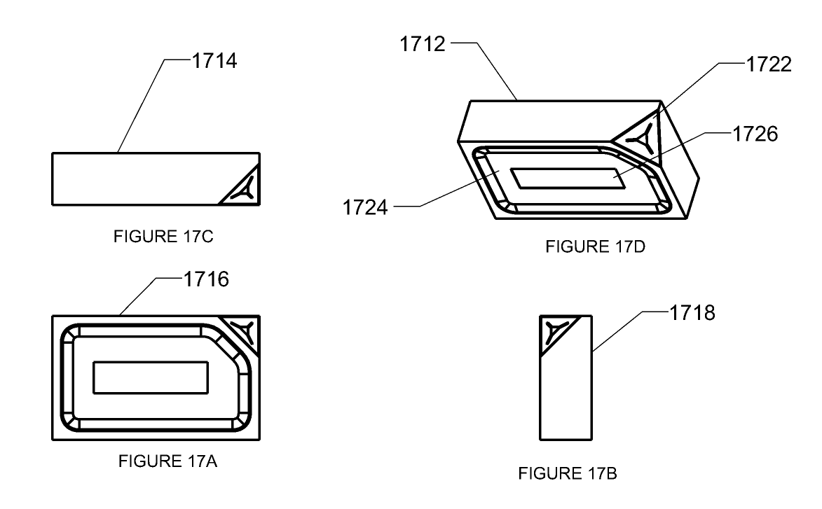

FIG. 17A is a front elevational view of a rectangular prism with one corner chamfered, a stylized triangular icon on the face of that chamfer, a scooped area in the front with a metallic insert, and a rectangular recess inside the insert. Referring to FIG. 17A, this view 1716 has one chamfered corner. FIG. 17B is a right elevational view of a rectangular prism with one corner chamfered, a stylized triangular icon on the face of that chamfer, a scooped area in the front with a metallic insert, and a rectangular recess inside the insert. Referring to FIG. 17B, this view 1718 has one chamfered corner. FIG. 17C is a top elevational view of a rectangular prism with one corner chamfered, a stylized triangular icon on the face of that chamfer, a scooped area in the front with a metallic insert, and a rectangular recess inside the insert. Referring to FIG. 17C, this view 1714 has one chamfered corner. FIG. 17D is a trimetric view of a rectangular prism with one corner chamfered, a stylized triangular icon on the face of that chamfer, a scooped area in the front with a metallic insert, and a rectangular recess inside the insert. Referring to FIG. 17D, this view 1712 has one chamfered corner 1722 a removed center portion 1724 and a metallic insert 1726.

It will be readily understood that the components of the application, as generally described and illustrated in the figures herein, may be arranged and designed in a wide variety of different configurations. Thus, the detailed description of the embodiments is not intended to limit the scope of the application as claimed, but is merely representative of selected embodiments of the invention.

One having ordinary skill in the art will readily understand that the application as discussed above may include hardware elements in configurations that are different than those which are disclosed. Therefore, although the application has been described based upon these preferred embodiments, it would be apparent to those of skill in the art that certain modifications, variations, and alternative constructions would be apparent, while remaining within the spirit and scope of the invention. In order to determine the metes and bounds of the invention, therefore, reference should be made to the appended claims.

What is claimed is:

1. An apparatus comprising:
a substantially rectangular housing comprising six primary sides; and
at least one chamfered corner contiguous with at least three of the six primary sides.

2. The apparatus of claim 1, wherein the chamfered corner has a triangular shaped surface area.

3. The apparatus of claim 2, wherein the triangular shaped surface area is an equilateral triangle.

4. The apparatus of claim 2, wherein the triangular shaped surface area is an isosceles triangle.

5. The apparatus of claim 1, further comprising:
at least one additional chamfered corner contiguous with at least three of the six primary sides.

6. The apparatus of claim 5, wherein the at least one additional chamfered corner is contiguous with only two of the same three primary sides as the chamfered corner.

7. The apparatus of claim 5, wherein the at least one additional chamfered corner is contiguous with one of the same three primary sides as the chamfered corner.

8. The apparatus of claim 1, further comprising:
at least three additional chamfered corners each of which is contiguous with at least three of the six primary sides.

9. The apparatus of claim 1, wherein the at least three additional chamfered corners are each contiguous with a same one of the six primary sides.

10. The apparatus of claim 1, wherein the chamfered corner comprises at least one secondary side that has less surface area than the six primary sides.

11. The apparatus of claim 1, wherein at least one of the six primary sides has been removed except for a lip portion that has a substantially smaller surface area than surface areas of the other five primary sides.

12. The apparatus of claim 1, further comprising:
a deformable insert located inside the housing which is exposed to the exterior of the housing via a removed face and which is contiguous with the lip portion.

13. The apparatus of claim 12, wherein the deformable insert is a deformable speaker.

14. The apparatus of claim 12, wherein the deformable insert is an electronic display with at least one chamfered corner.

15. An apparatus comprising:
a housing comprising six sides; and
at least one chamfered corner contiguous with at least three of the six sides, wherein a surface area of the chamfered corner is substantially less than a surface area of any of the six sides.

16. The apparatus of claim 15, wherein the chamfered corner has a triangular shaped surface area.

17. The apparatus of claim 16, wherein the triangular shaped surface area is an equilateral triangle.

18. The apparatus of claim 16, wherein the triangular shaped surface area is an isosceles triangle.

19. The apparatus of claim 15, further comprising:
at least one additional chamfered corner contiguous with at least three of the six sides.

20. The apparatus of claim 19, wherein the at least one additional chamfered corner is contiguous with only two of the same three sides as the chamfered corner.
